(19) United States
(12) Patent Application Publication
(10) Pub. No.: US 2020/0285574 A1
(43) Pub. Date: Sep. 10, 2020

(54) Method of using a symbol transformer machine, and symbol transformer machine, for performing information storage and memory functions

(71) Applicant: Tegze P. Haraszti, Newport Beach, CA (US)

(72) Inventor: Tegze P. Haraszti, Newport Beach, CA (US)

(21) Appl. No.: 16/350,112

(22) Filed: Sep. 26, 2018

(51) Int. Cl. G06F 12/02; G06F 3/06; G11C 16/10; G11C 16/04; H03M 13/37

(52) U.S. Cl. CPC G06F 12/0246; G06F 3/0679; G06F 2212/7201; G11C 16/0483; H03M 13/37; G11C 16/10

(57) ABSTRACT

Method and machine for storing massive amounts of information in very small spaces; and for combining that with the characteristics of very high speed program, write and read operations, small power consumption, great environmental tolerance, radiation hardness and reliability, small size and weight, at low costs, are provided. The method associates, couples and transforms content symbol and address symbol to each other, stores and memorizes the associations, couplings and transforms, by and in a symbol transformer machine. The first augmentation dissects the symbol into symbol parts, operates on and with symbol parts, and combines symbol parts. The second augmentation operates on and with polyadic numbers and polyadic number parts. The third and fourth augmentations comprise conversions and auxiliary storage of symbols and symbol parts, respectively. Embodiments of symbol transformer machine comprise one or a plurality of crosspoint arrays, transistor circuits, memory devices, logic gates, registers, transcoders, and auxiliary memories. In any combination, the invention allows for the use of any and all of the processing steps, augmentations and embodiments.

### CROSS-REFERENCE TO RELATED APPLICATIONS

This application claims the benefit of provisional patent application, Application No. 62/606,626, filed Sep. 30, 2017, by the present inventor

### FEDERALLY SPONSORED RESEARCH OR DEVELOPMENT

None

### SEQUENCE LISTING

None

### SMALL BUSINESS OR MICRO ENTITY

Yes

### TECHNICAL FIELD

The present invention relates to symbol transformation methods and symbol transformer machines which provide information storage and memory functions.

### BACKGROUND/PRIOR ART

Information storage and memory methods and machines are fundamental to the operation and performance of most computing, data processing, telecommunication, commercial, military, spaceborne, airborne, terrestrial and many other systems. Prior art information storage and memory methods and machines are the ones which severely limit the characteristics of operational speed, power consumption, environmental tolerance, radiation hardness, reliability, size, weight and cost of most contemporary systems.

Traditionally, information storage and memory methods and machines work with symbols represented by codes. A symbol is something that stands for or suggests something else by reason of association, convention, relationship or resemblance. A code is a system of symbols. Content symbols stand for the information to be programmed or written, stored and memorized, and read. Address symbols identify the locations where the content symbols are to be programmed or written, stored and memorized, or read.

The prior art method and machine represent both the content symbol and the address symbol in binary code as a multiplicity of content code words and a multiplicity of address code words. A content information store stores and memorizes the multiplicity of content code words in a great multiplicity of memory elements under the addresses provided by the multiplicity of address code words. In the prior art machines, with increasing number and size of the content code words and the address code words, the number of memory and constituent elements, and the complexity greatly aggrandize.

Satisfaction of the basic need, for storing and memorizing astronomical amounts of information, demands astronomical amounts of information storage capacities and, in turn, of memory and constituent elements and of very high complexities. Yet, with the use of the prior art, the aggrandizing amount of memory and constituent elements and the compounding complexity results in stunning degradation in said characteristics, except the cost per bit figure.

As a result of technological and technical developments, most of the contemporary information storage and memory machines are embodied in semiconductor memory devices. The quantity and the variety of semiconductor memories are astonishing. Semiconductor, specifically complementary-metal-oxide-semi-conductor (CMOS) memories are traded as mass products worldwide; and the patent search engine returned about 133 million semiconductor memory device related patents.

Disc memories are important parts of computing systems. However, semiconductor memories, particularly solid state discs (SSDs) are expected to squeeze out the mechanically rotating optical, magnetic and other memories of future applications.

The various prior art methods and machines lay on the common base briefed under both initial figures of this application.

Table 1 shows references introducing contemporary information storage and memory machines and devices. The inventor of the present application in his book titled “CMOS Memory Circuits” describes the classification, types, functions, characteristics, constituent elements, and provides a mathematical-physical analysis and improvements of and for contemporary memories. Among his granted relevant patents, the U.S. Pat. No. 34,169,233 has been used and of key importance in the vast majority of all information storage and memory machines and devices. A. K. Sharma in his book titled “Advanced Semiconductor Memories” surveys and details the architectures, designs, and applications of semiconductor memories. B. Prince in his book titled “Emerging Memories: Technologies and Trends” provides background and description of technology, function, properties and application of new memory devices,

TABLE 1

| Publication Title | Year | Author |
|---|---|---|
| CMOS Memory Circuits | 2000 | Haraszti |
| Advanced Semiconductor Memories | 2000 | Sharma |
| Emerging Memories | 2002 | Prince |

No patent, patent application, publication or any information has been found that proposes a method of using a symbol transformer machine to perform information storage and memory functions, that uses and transforms content symbols and address symbols, that uses and transforms content symbol parts and address symbol parts, that programs or writes, stores and memorizes, and reads associations, couplings and transforms between and among symbols and symbol parts, that dissects symbols, stores and combines symbol parts, among others. No prior art symbol transformer machine has been found that is used and configured to perform information storage and memory functions, that is a new application of known crosspoint arrays, transistor circuits, memory devices, logic circuits, and that is augmented with dissector-separator, combiner-integrator, converter, transcoder and auxiliary memory.

Table 2 is a tabulation of some prior art patents which may appear relevant. U.S. Pat. No. 7,644,335 B2 proposes linear transformation of data arranged in a plurality of source symbols to overcome of excessive memory constraints in a sender-receiver type of data transmission. U.S. Pat. No. 6,341,412 B2 and EP 1532739 B1 propose to generate statistics of symbol appearance frequencies, level those frequencies, and transform to other formats which may be efficiently stored in non-volatile memories, and which alleviate fundamental limitations inherent to prior art non-volatile data storage and memory devices. U.S. Pat. No. 4,811,400 A proposes a method of transforming symbolic text data to symbolic speech data for text-to-speech word processing and cryptographic uses. U.S. Pat. No. 811,439 B2 proposes a data processing method comprising three data transformation and filtering to reduce memory requirements specifically for orthogonal frequency division multiplexing. CA 2179758 C proposes method and apparatus for performing fast Hadamard transform to optimize the use of memory resources in data processing systems.

TABLE 2

| Patent Number | Kind Code | Priority Date | Patentee |
|---|---|---|---|
| U.S. Pat. No. 7,644,335 | B2 | Jun. 10, 2005 | Luby |
| U.S. Pat. No. 6,941,412 | B2 | Aug. 29, 2002 | Geoffrey |
| EP 1532739 | B1 | Aug. 29, 2002 | Geoffrey |
| U.S. Pat. No. 4,811,400 | A | Dec. 27, 1984 | Fisher |
| US 811439 | B2 | Sep. 24, 2008 | Hsueh |
| CA 2179758 | C | Dec. 22, 1993 | Dahesh |

### SUMMARY OF THE INVENTION

A method of using a symbol transformer machine and symbol transformer machine for performing information storage and memory functions, including but not limited to the operations of program and write, store and memorize, normal and content addressable read, are provided. It transubstantiates the symbol transformer machine into an information storage and memory machine, that performs the operations by creating, storing, memorizing and manipulating associations, couplings and transforms between and among symbols and symbol parts. The embodiments of the symbol transformer machine and their constituent parts are new uses and new combinations of known machines, devices and elements.

### Advantages of the Invention

The new method and machine succeed to store massive amounts of information in very small spaces; and to combine that with very high speed access, program, write and read operations, very small power consumption, great environmental tolerance, radiation hardness and reliability, very small device size, little weight, and low manufacturing cost. Such combinations of improvements cannot or can only limitedly be produced by the prior art.

In systems, the invention reduces the extent of the information storage and memory hardware to a fraction of that of the state-of-the-art, while it greatly improves the overall performance and manufacturing characteristics of the machine and device. Those, in turn, allow for designing, fabricating and manufacturing such very complex high performance systems at low costs, which were believed uneconomical, and unrealizable.

The method and machine of innovation solve and circumvent the limitations and trade-offs inherent to the prior art, and resolves problems which were thought insolvable. They omit elements and greatly reduce the number of memory and constituent elements, and the complexity. They provide operative performance that is unachievable by use of the prior art. They satisfy long-existing needs. Although they are classified into the one of the most crowded arts where small advances carry great weight, the invention offers great advancements carrying large weight in the development of the art.

The great evolutional improvement in such characteristics of the prior art was achieved by manufacturing technologies that reduced the transistor and feature sizes to tenth of the nanometer range. Further reduction of feature sizes are limited by fundamental issues in device physics and by the economy of production.

### FIGURES—DRAWINGS

FIG. 1 illustrates the basic prior art method for providing information storage and memory functions.

FIG. 2 illustrates the prior art generic machine for performing information storage and memory functions.

FIG. 3 illustrates a basic method of invention of using a symbol transformer machine for performing information storage and memory functions.

FIG. 4 illustrates a first augmented method of invention further comprising dissection of symbols, operation on and with symbol parts, and combination of symbol parts.

FIG. 5A shows the mathematical formula for polyadic number representation, and FIG. 5B illustrates the first augmented method applied to polyadic numbers.

FIG. 6 illustrates a second augmented method of invention further comprising conversion of symbols and symbol parts.

FIG. 7 illustrates a third augmented method of invention further comprising storing symbols and symbol parts.

FIG. 8 illustrates the method of invention further comprising one of the many possible combinations of the steps for providing storage and memory functions.

FIG. 9 illustrates a generic symbol transformer machine of invention comprising FIG. 9A one, FIG. 9B a plurality of differing, and FIG. 9C a plurality of approximately same symbol transformer means.

FIG. 10 illustrates the machine of invention embodied in a crosspoint array.

FIG. 11 illustrates the machine of invention embodied in a transistor circuit.

FIG. 12 illustrates the machine of invention embodied in memory means.

FIG. 13 illustrates the machine of invention embodied in logic gate means.

FIG. 14 illustrates a first augmented machine of invention configured to operate with symbol parts further comprising dissector-separator means and combiner-integrator means.

FIG. 15 illustrates the first augmented machine of invention, wherein the dissector-separator means and combination integrator means are embodied in symbol registers.

FIG. 16 illustrates a second augmented machine of invention further comprising symbol converter means.

FIG. 17 illustrates the second augmented machine of invention, wherein the symbol converter means are embodied in transcoders.

FIG. 18 illustrates a third augmented machine of invention further comprising auxiliary memory means.

FIG. 19 illustrates the third augmented machine of invention, wherein the auxiliary memory means are embodied in read only and programmable memories.

FIG. 20 illustrates the machine of invention, further comprising one of the many possible combinations of the introduced constituent elements.

### DESCRIPTION

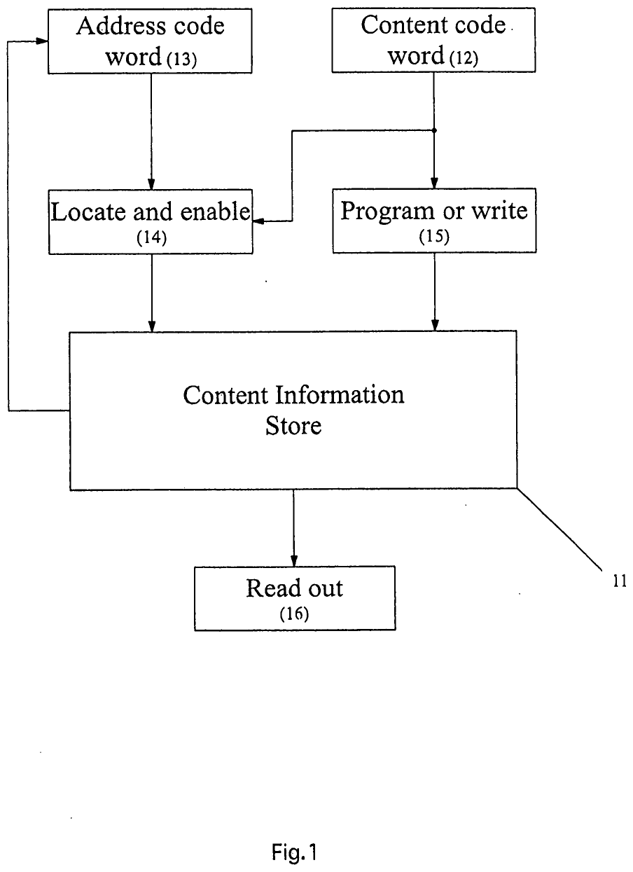

FIG. 1 is a flowchart illustrating the basic prior art method for performing information storage and memory functions.

Information storage and memory functions include, but are not limited to program or write, store and memorize, normal and content addressable read.

The prior art method is tied to the hardware of content information store 11. Content and address information are represented in a binary code as content code word (12) and address code word (13), respectively. Content information store 11 is organized in addressable locations. Under each address, a content code word (12) is stored in a plurality of memory elements or memory cells. Each memory element allows for programming or writing, storing and memorizing and reading one or a plurality of information units.

The prior art method performs the steps of

(a) program or write operation by using address code word to locate and enable (14) access to addressed memory elements in content information store 11, and by feeding content code word (12) to program or write (15) into the accessed memory elements;
(b) store and memorize operation by storing and memorizing the programmed or written content code word (12) in the memory elements of content information store 11;
(c) normal read operation by using address code word (13) to locate and enable (14) access to the addressed memory elements in content transformation store 11, and by extracting content code word (14) to read out (16) from the accessed memory elements;
(d) content-addressable read operations by using content code word (12) or a part of content code word (12) to locate and enable access (14) to content-addressable memory elements, and to read out (16) content code word (12) and address code word (13) from the accessed memory elements of content information store 11.

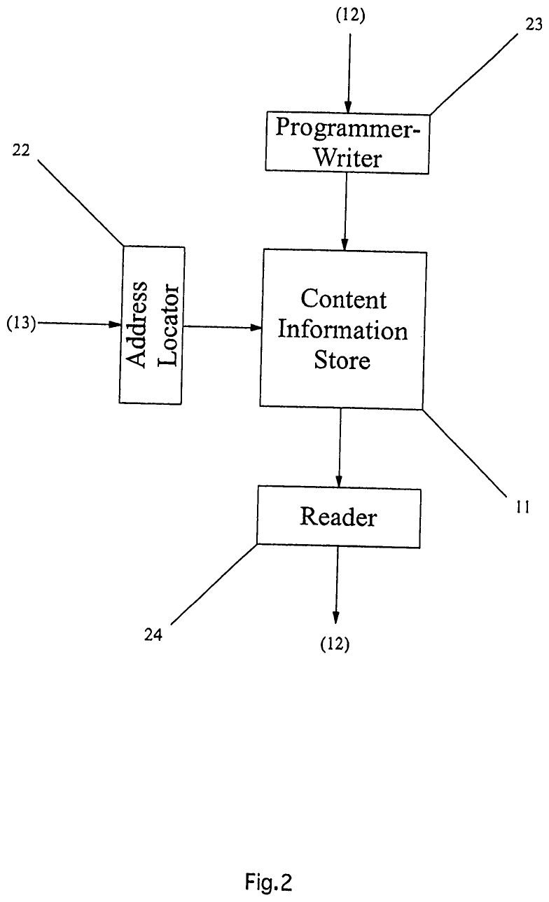

FIG. 2 is a schematic diagram illustrating the prior art generic information storage and memory machine.

The prior art information storage and memory machine comprises

one or a plurality of content information stores 11 for storing and memorizing a plurality of content code words (12) in a multiplicity of memory elements of content information stores 11;
one or a plurality of address locators 22, coupled with and to one or a plurality of content information stores 11, to receive address code (13), to locate and enable access (14) to addressed memory cells in content information stores 11;
one or a plurality of programmer-writers 23, coupled with and to one or a plurality of content information store 11, to receive content code word (12), and to program, reprogram, write, rewrite or otherwise alter content code word (12) in the multiplicity of memory elements of one or a plurality of content information stores 11; at application of read-only-memory cells as content-information stores 11, programmer-writer 23 is not a constituent element of the prior art machine;
one or a plurality of readers 24, coupled to and with one or a plurality of content information stores 11, to receive content code word (12) from content information store 11, to read content code (12) stored and memorized in the memory elements of content information store 11.

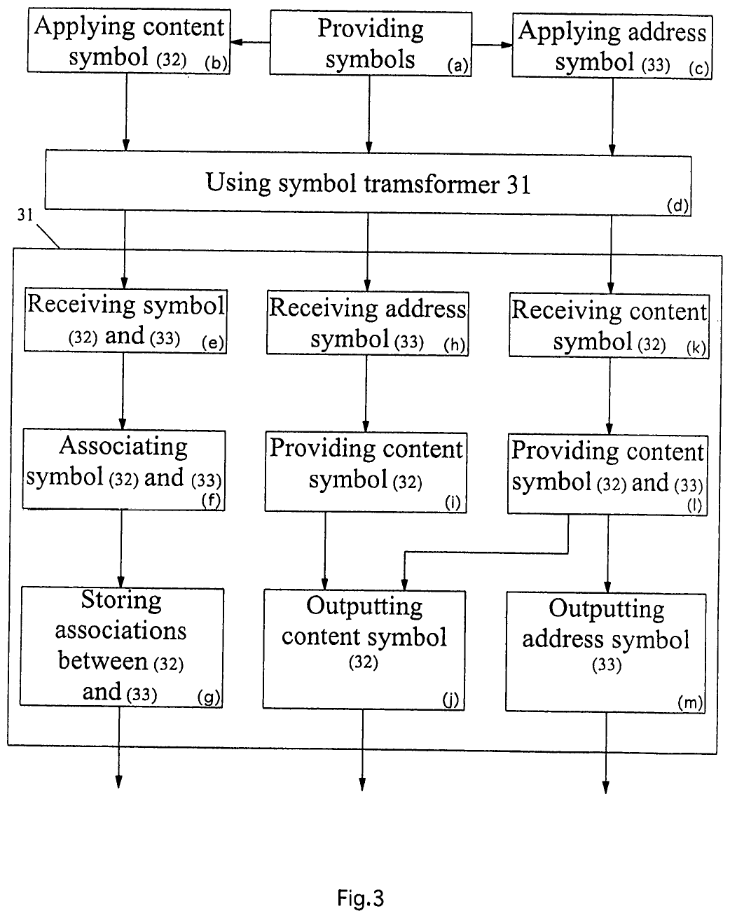

FIG. 3 is a flowchart illustrating a basic method of invention of using a symbol transformer machine for performing information storage and memory functions.

Information storage and memory functions include, but are not limited to program or write, store and memorize, normal or content addressable or both types of read operations.

The method of invention performs the operations on and with pluralities of symbols; content symbols, address symbols, content symbol parts and address symbol parts. In comparison to the prior art, the method of invention greatly reduces the number of memory elements, the number of constituent elements; and the complexity, whereby the characteristics of operation and speed, power consumption, reliability, radiation hardness, size weight cost of information storage and memory machines, and of systems incorporating such machines, greatly improve.

The method of invention comprises the steps of

(a) providing symbols for something standing for or suggesting something else by reason of association, convention, relationship;
(b) applying content symbol (32), for information standing for or suggesting a thing or function to store and memorize;
(c) applying address symbol (33), for information standing for or suggesting an address for the location of content symbol (32);
(d) using symbol transformer machine 31 to perform the information storage and memory functions, including but not limited to said operations, by creating associations, couplings and transforms between and among and between the symbols, content symbols, address symbols, content symbol parts and address symbol parts, and by storing and memorizing the associations, couplings and transforms.

The program and write operation comprises the steps of

(e) receiving content symbol (32) and address symbol (33);
(f) associating, coupling and transforming content symbol (32) with and to address symbol (33) or doing so in reverse order.

The store and memorize operation comprises the step of

(g) storing and memorizing associations, couplings and transforms formed among symbols, between content symbol (32) and address symbol (33).

The normal read operation comprises the steps of

(h) receiving address symbol (33);
(i) providing content symbol (32) associated, coupled and transformed with and to received address symbol (33);
(j) outputting content symbol (32).

The content addressable read operation comprises the steps of

(k) receiving content symbol (32);
(l) providing content symbol (32) and address symbol (33) associated, coupled and transformed with and to received content symbol (32);
(m) outputting content symbol (32), or address symbol (32) or both content symbol (32) and address symbol (33).

The method of invention, wherein the symbols, content symbol (32) and address symbol (33) are represented in one or a plurality of codes, where a code is a system of symbols, reduces the number of memory elements in and the complexity of the machine 31. Whereby said characteristics improve.

The method of invention, wherein the symbols, content symbol (32) and address symbols (33) can be anything or any function, allows for using of a great variety and combination of symbol types. Whereby the application of the method and machine greatly expands.

The method of invention, wherein the symbols, content symbol (32) and address symbol (33) are represented by a plurality of numbers in one or a plurality of number systems, reduces the number of memory and constituent elements and the complexity of the machine, and the complexity of the operations. Whereby said characteristics greatly improve.

The method of invention, wherein the number system is the decimal number system, having ten cyphers representing 0, 1, 2, 3, 4, 5, 6, 7, 8 and 9, conforming with human computing and data processing traditions, reduces and eliminates encoding, decoding and other symbol conversion processing, and simplifies the operations. Whereby said characteristics further improve.

The method of invention, wherein the number system is the binary number system, having two cyphers representing 0 and 1, complying with prior art computing and data processing standards, reduces and eliminates encoding, decoding and other symbol conversion processes, and simplifies the operations. Whereby said characteristics further improve.

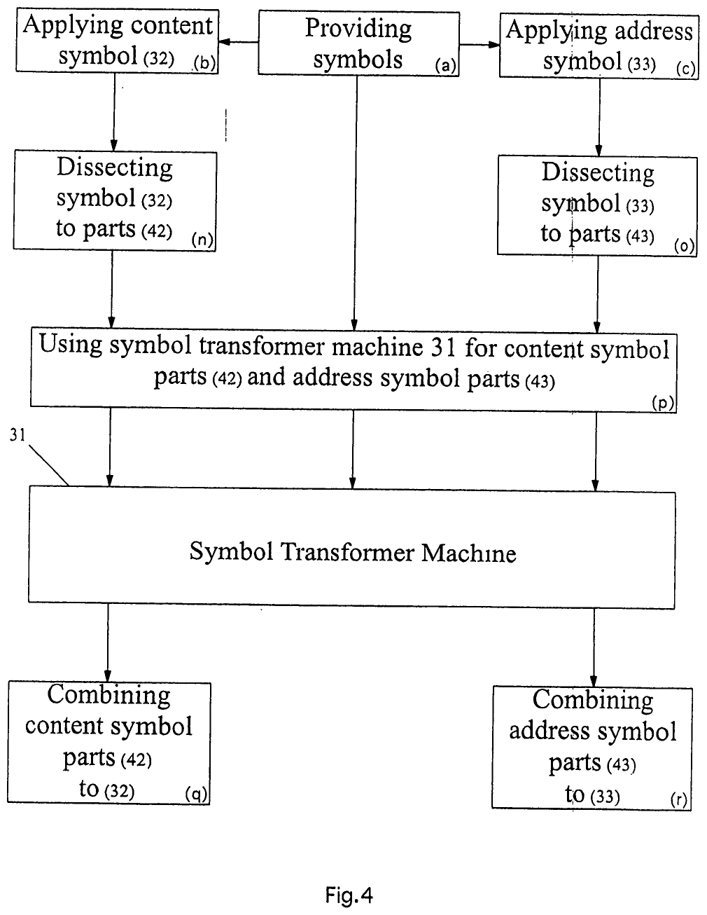

FIG. 4 is a flowchart illustrating a first augmented method of invention further comprising dissection of symbols, operation on and with symbol parts, and combination of symbol parts.

The first augmented method of invention greatly reduces the number of memory and constituent elements and the complexity of symbol transformer machine 31. Whereby said characteristics greatly improve.

The first augmented method of invention comprises the supplemental steps of

(n) dissecting and separating content symbol (32) to a plurality of content symbol parts (42);
(o) dissecting and separating address symbol (33) to a plurality of address symbol parts (43);
(p) using symbol transformer machine 31 for performing the operations on and with a plurality of content symbol parts (42) and address symbol parts (43);
(q) combining and integrating a plurality of content symbol parts (42) to form address symbol (32);
(r) combining and integrating a plurality of address symbol parts (43) to form address symbol (33).

The first augmented method of invention, wherein the size of content symbol parts (42) and address symbol parts (43) is the same, further reduces the number of memory elements and the complexity of symbol transformer machine 31. Whereby said characteristics further improve.

The first augmented method of invention, wherein the number and content symbol parts (42) and the number of address symbol parts (43) is the same, further reduces the complexity of symbol transformer machine 31. Whereby said characteristics further improve.

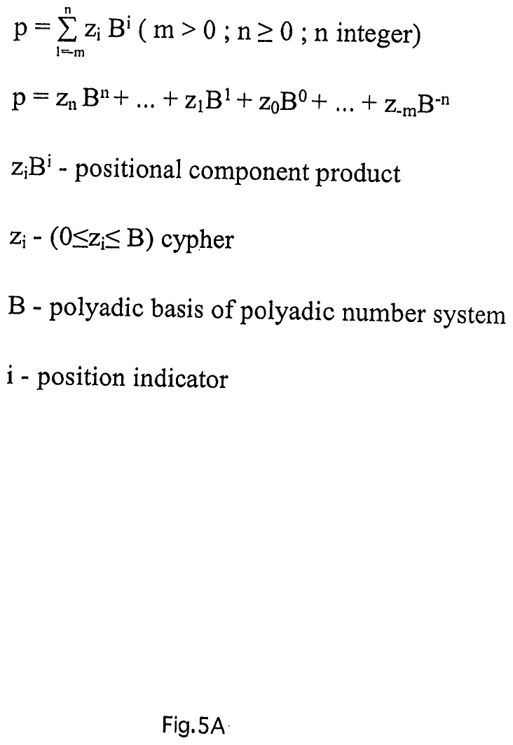

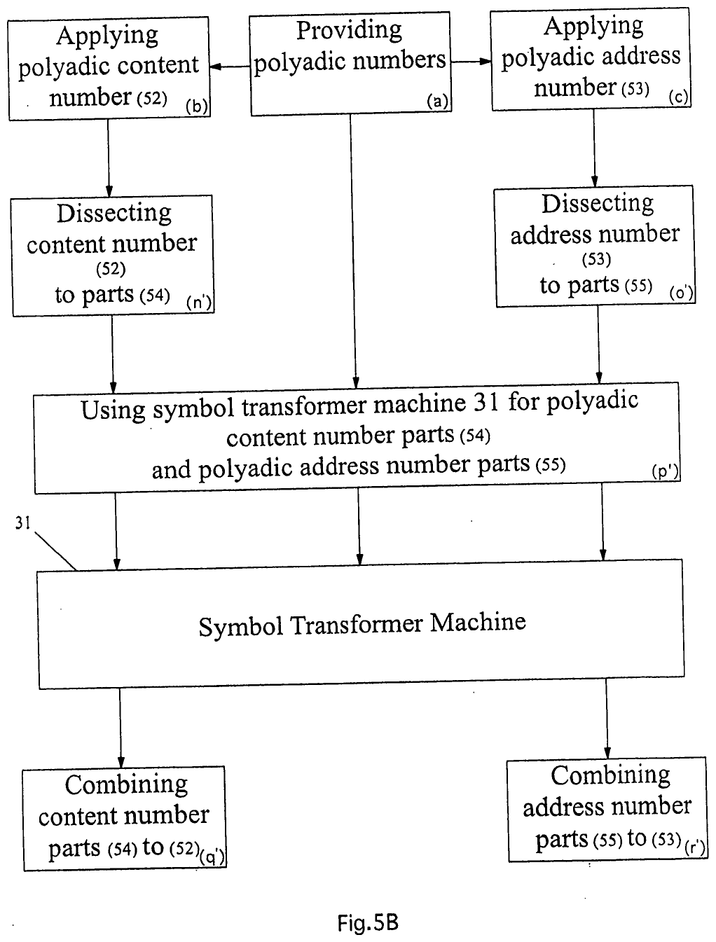

FIG. 5A is a mathematical formula expressing the law of representation for a polyadic number system, and FIG. 5B is a flowchart illustrating the first augmented method of invention, wherein the symbols are polyadic numbers, and the symbol parts are polyadic symbol parts.

The law of representation for the polyadic number system defines a polyadic number p as the combinative sum of a plurality of positional component products zᵢB¹−s. Where zᵢ is a positional cypher on position i (0≤zᵢBⁱ) i is the position indicator, and B is the polyadic basis of the polyadic number system.

Performing the operations with and on polyadic numbers and polyadic number parts, further greatly reduces the number of constituent and memory elements and the complexity of the symbol transformer machine 31. Whereby said characteristics further greatly improve.

The first augmented method of invention, wherein content symbol (32), content symbol part (42), address symbol (33) and address symbol part (43) are polyadic content number (52), polyadic content number part (54), polyadic address number (53) and polyadic address number part (55), respectively, comprises the supplemental steps of

(n′) dissecting and separating polyadic content number (52) to a plurality of polyadic content symbol parts (54);
(o′) dissecting and separating polyadic address symbol (53) to a plurality of polyadic address symbol parts (55);
(p′) using symbol transformer machine 31 for performing the operations on and with one or plurality of polyadic content number parts (54) and of polyadic address number parts (55);
(q′) combining and integrating a plurality of polyadic content number parts (54) to form polyadic content number (52);
(r′) combining and integrating a plurality of polyadic address number parts (55) to form polyadic address number (55).

The method of invention, wherein polyadic content number parts (54) and polyadic address number parts (55) are products of positional cypher a and the polyadic basis B of the polyadic number system on the power indicated by position i, further reduces the complexity of symbol transformer machine 31. Whereby said characteristics further improve.

The method of invention, wherein polyadic content number parts (54) and polyadic address number parts (55) are polyadic content cyphers, and polyadic address cyphers, respectively, in a common single polyadic number system having the common single basis B, further reduces the number of constituent elements and the complexity of symbol transformer machine 31. Whereby said characteristics further improve.

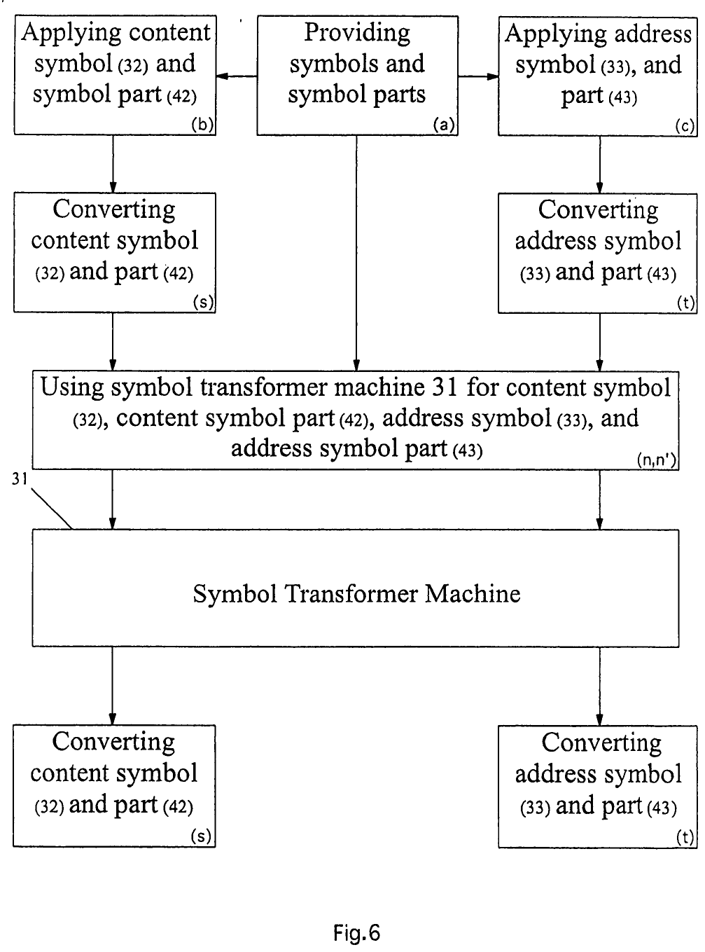

FIG. 6 is a flowchart illustrating a second augmented method of invention further comprising conversion of one or a plurality of symbols, symbol parts, or a combination of the symbol presentments.

Converting a first symbol, a first symbol part, or a combination of the first symbol presentments standing for or suggesting a specific thing or function to a second symbol, second symbol part, or a combination of the second symbol presentments standing for or suggesting the same specific thing or function as the first symbol presentments do, simplifies the operations and reduces the number of constituent elements of symbol transformer machine 31. Whereby said characteristics further improve.

The second augmented method of invention comprises the supplemental steps of

(s) converting content symbol (32), content symbol part (42), or a combination of the content symbol presentments;
(t) converting address symbol (33), address symbol part (43), or a combination of the address symbol presentments.

The second augmented method of invention, wherein the steps of converting are steps of transcoding, including but not limited to decoding, encoding or combined decoding-encoding; further reduces the number of memory elements and the complexity of aid operations and symbol transformer 31. Whereby said characteristics further improve.

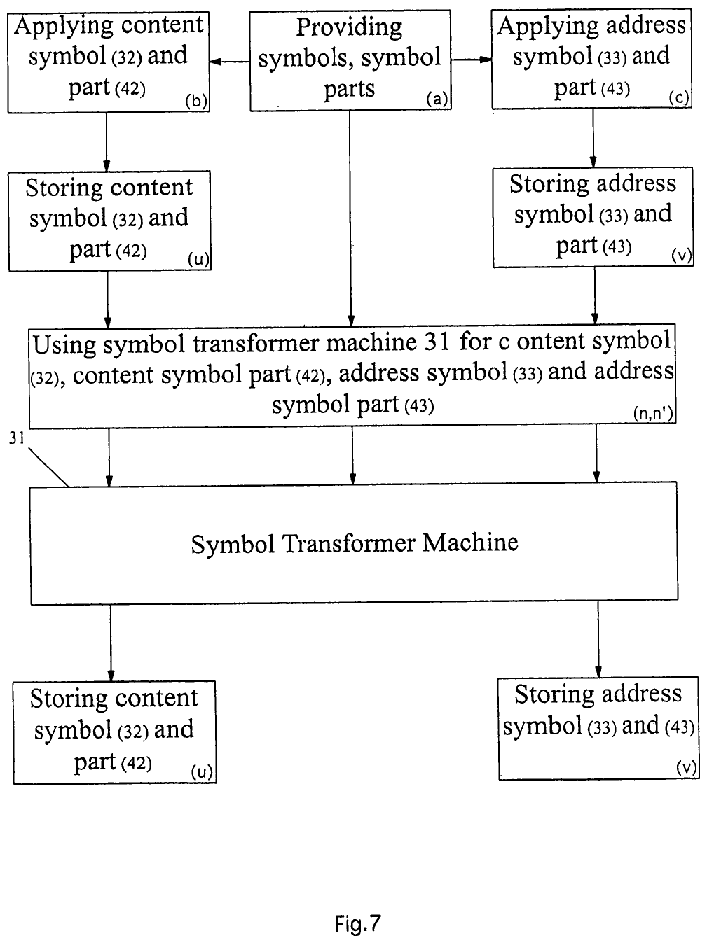

FIG. 7 is a flowchart illustrating a third augmented method of invention further comprising storing a plurality of the symbols, symbol parts, or a combination of the symbol presentments.

Storing symbols, symbol parts, or a combination of the symbol presentments supplements and takes part in performing the operations, provides symbol presentments and assists in timing for symbol transformer machine 31. It reduces the number of the memory and constituent elements and the complexity of symbol transformer machine 31. Whereby said characteristics improve.

The third augmented method of invention comprises the supplemental steps of

(u) storing content symbol (32), or content symbol parts (42), or a combination of the content symbol presentments;
(v) storing address symbol (33), or address symbol parts (43), or a combination of the address symbol presentments.

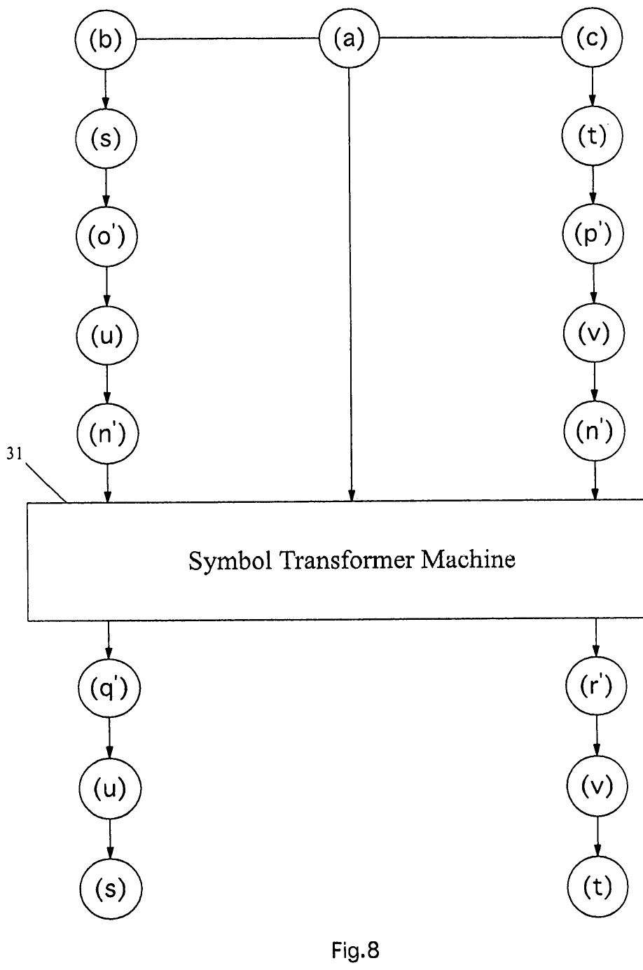

FIG. 8 is a flowchart illustrating the method of invention, further comprising one of the many possible combinations of the described steps.

The method of invention comprises the use of any and all of the plurality of the steps, and one or a plurality of the additional steps, in any combination to any apparatus for specializing, improving or optimizing said characteristics. Whereby said characteristics, number and variety of applications and manufacturability improve.

One of the many combinations of the steps comprises

(a) providing symbols, (b) applying content symbols, (c) applying address symbol, (s) converting content symbol to polyadic content number, (i) converting address symbol to polyadic address number, (o′) dissecting polyadic content number into parts, (p′) dissecting polyadic address number into parts, u. storing polyadic address number parts, (v) storing polyadic address number parts, (n′) using symbol transformer machine 31 for polyadic content number parts, (q′) combining polyadic content number parts to polyadic content number, (r′) combining polyadic address number parts to polyadic address number, (u) storing polyadic content number, (v) storing polyadic address number, (s) converting polyadic content number to content symbol, (t) converting polyadic address number to address symbol.

The method of invention is for use in any system, including but not limited to computing, data processing, telecommunication, commercial, military, airborne, waterborne, terrestrial and other systems. Whereby said characteristics of the system improve.

The method of invention, furthermore, can be used for creating and performing logic, mathematical, and other functions to and in systems. Whereby said characteristics of the system improve.

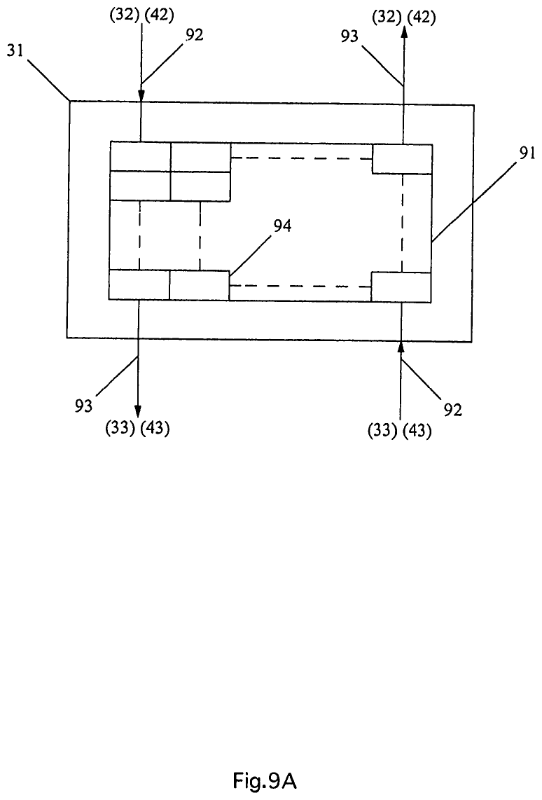

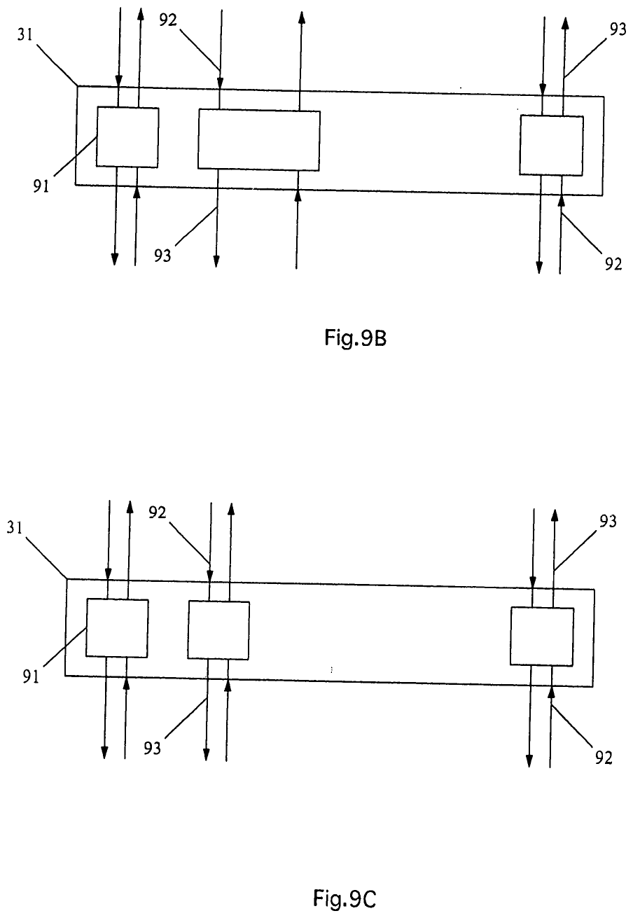

FIG. 9 includes three schematic diagrams illustrating a generic symbol transformer machine of invention for performing information storage and memory functions, comprising FIG. A one, FIG. B a plurality of differing, and FIG. C a plurality of approximately same symbol transformer means.

The information storage and memory functions include, but are not limited to, program or write, store and memorize, normal read or content addressable read or both types of read operations.

Symbol transformer machine 31 changes a symbol that stands for or suggests a thing or function to another symbol that stands for or suggests another thing or function.

To provide information storage and memory functions, symbol transformer machine 31 needs only a small fraction of the memory and constituent elements and the complexity of those needed for the prior art machine, for performing the same or similar information storage and memory functions. Whereby the characteristics of operational speed, power consumption, environmental tolerance, radiation hardness, reliability, size, weight and cost of machine 31 become greatly superior to the characteristics of the prior art machine and systems incorporating such machine.

Symbol transformer machine 31 comprises

a. one or a plurality of symbol transformer means 91, for performing information storage and memory functions, including but not limited to said operations, by creating associations, couplings and transforms between and among content symbol (32), address symbol (33), content symbol part (42) and address symbol part (43), in any combinations of the symbol presentations, and by storing and memorizing those associations, couplings and transforms;
b. one or a plurality of symbol input means 92, coupled with, to or incorporated by symbol transformer means 91, for receiving content symbol (32), address symbol (33), content symbol part (42) and address symbol part (43);
c. one or a plurality of symbol output means 93, coupled with, to or incorporated by symbol transformer means 91, for outputting content symbol (32), address symbol (33), content symbol part (42) and address symbol part (43).

Input means 92 and output means 93 combined in united symbol input-output means reduces the number of constituent elements and the complexity of the symbol transformer machine 31. Whereby said characteristics improve.

Symbol transformer machine 31, wherein symbol transformer means 91 comprise

d. a plurality of memory element means 94, coupled directly or indirectly with and to input means 92 and output means 93, for providing storage and memorization of the associations, couplings and transforms between and among content symbol (32), address symbol (33), content symbol part (42) and address symbol part (43).

Memory element means 94 include, but are not limited to, programmable, write-read, fixed read-only, content addressable, shift register or any other type of memory cells, machines and devices.

Symbol transformer machine 31, wherein a plurality of symbol transformer means 91 is configured to be the same or similar, reduces the complexity of machine 31. Whereby the cost and manufacturability of machine 31 improves.

Symbol transformer machine 31, configured and implemented in one or a plurality of technologies, including but not limited to comprising a. digital, b. analog, c. electric, d. electronic, e. magnetic, f. semiconductor, g. mechanic, h. sound, i, thermal, j, micro, k. nano, l. transistor, m. atomic, n. subatomic, o. nuclear, p. radiation hardened, q. light, r. quantum, s. wave, t. hydraulic, u. biological, v. pervasive, z. macro categories, allows for using a variety and combinations of implementation methods. Whereby the application area and flexibility expands.

Symbol transformer machine 31, configured to perform the operations in one or a plurality of codes, reduces the complexity of the machine. Whereby said characteristics improve.

Symbol transformer machine 31, configured to perform the operations in one or a plurality of number systems, reduces the number of memory and constituent elements and the complexity of machine 31. Whereby said characteristics greatly improve.

Symbol transformer machine 31, configured to perform the operations in either one or both of the decimal and the binary systems, complies with human traditions, standard computing and data processing, reduces and eliminates encoding, decoding and other symbol converter Machines and devices. Whereby said characteristics greatly improve.

Symbol transformer machine 31, configured to perform the operations on and with of plurality of signals of one or a plurality of conveyable and detectable physical quantities and qualities, which represent one or a plurality of content symbols (33), address symbols (34), content symbol parts (42) and address symbol parts (43), reduces the number of constituent elements and the complexity of the machine. Whereby said characteristics improve.

Signals include, but are not limited to, digital and analog signals.

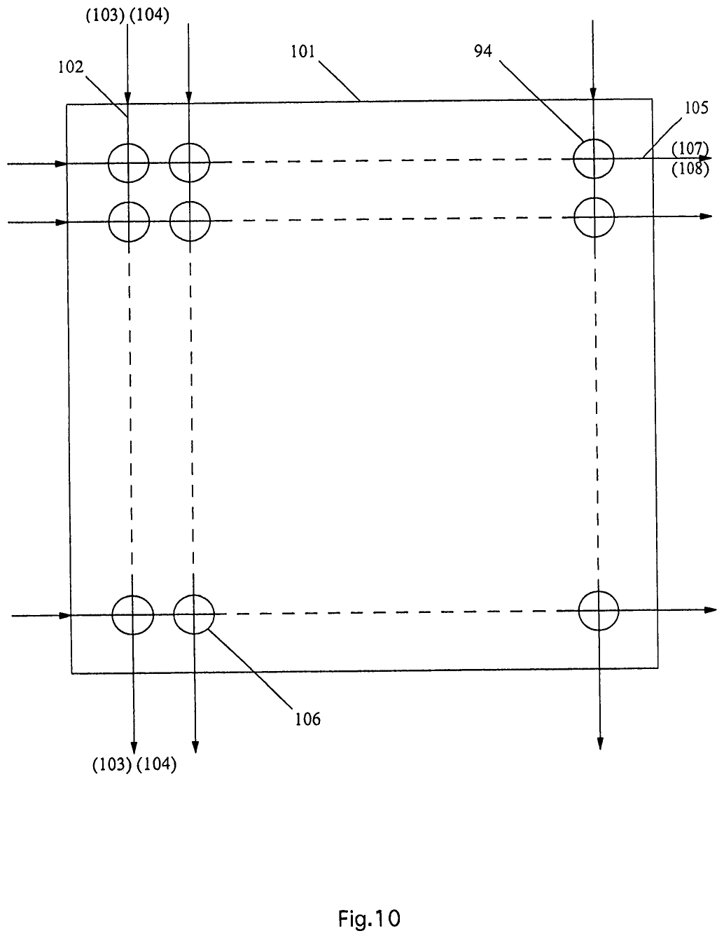

FIG. 10 is a schematic diagram illustrating symbol transformer machine of invention 31 embodied in crosspoint array 101.

Crosspoint array 101 perform the operations on and with signals, content signal (103), address signal (107), content signal part (104) and address signals part (108). Embodiments in crosspoint arrays reduce the complexity of the machine 31. Whereby said characteristics improve.

Crosspoint array 101 comprises

x. a plurality of first signal conveyor line means 102 for receiving, conveying and outputting content signal (103) or content signal part (104), or both types of content signal presentments;
y. a plurality of second signal conveyor or line means 105, arranged to form a plurality of crosspoints 106 with the plurality of first signal conveyor line means 102, for receiving, conveying and outputting address signal (107) or address signal part (108), or both types of address signal presentments;
z. a plurality of memory element means 94, coupled to first signal conveyor means 102 and second conveyor line means 105 at or about crosspoints 106 for providing programmable or writeable, storable and memorizable, or fixed conveyance or nonconveyance state.

Crosspoint arrays and their operation are well known machines and devices to those who are skilled in the art.

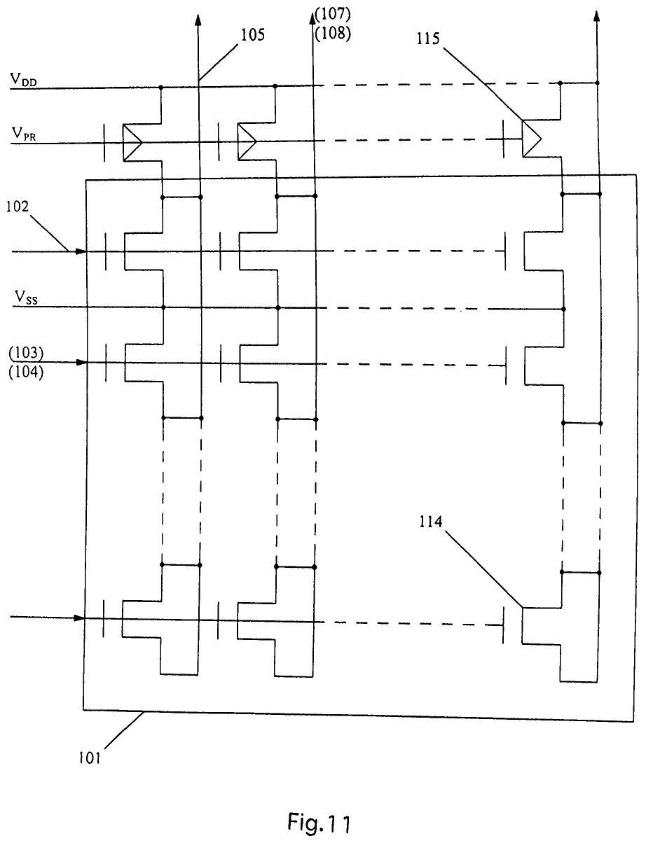

FIG. 11 is a circuit diagram illustrating the symbol transformer machine of invention 31 embodied in a transistor circuit in the configuration of crosspoint array 101.

Symbol transformer machine of invention 31, has many possible embodiments in various transistor circuits. One of those is a transistor circuit using the configuration of crosspoint array 101 comprises

x. a multiplicity of n-type transistors 114 coupled parallel to each other by their individual gate terminals, drain terminals and source terminals, for forming one or a multiplicity of input signal conveyor lines 102, output signal conveyor lines 105, and a common ground terminal Vₛₛ, respectively;
y. each of a multiplicity of p-type transistors 115 coupled by their individual drain terminals, gate terminals, and source terminals to output signal conveyor line 105, a united program and precharge voltage terminal V_{PR}, and a supply voltage terminal V_{DD}, respectively, for forming, in combination with the multiplicity of n-type transistors 119, one or a multiplicity of precharged or ratio type of NOR gates with the plurality of n-type transistors 114;
z. a plurality of voltage source terminals. V_{DD}, V_{PR}, and V_{SS}, coupled to the source terminals of and or a plurality of p-transistors 115, the gate terminals of one or a plurality of p-type transistors 115, the source terminals of the plurality of n-type transistors 114, respectively, for providing energy for programming and operating the transistor circuit.

The hardware and operation of transistor circuits performing symbol transformation, including but not limited to the transistor circuit in the configuration of the crosspoint array embodied in precharged or ratio NOR gates, are well known to those who are skilled in the art.

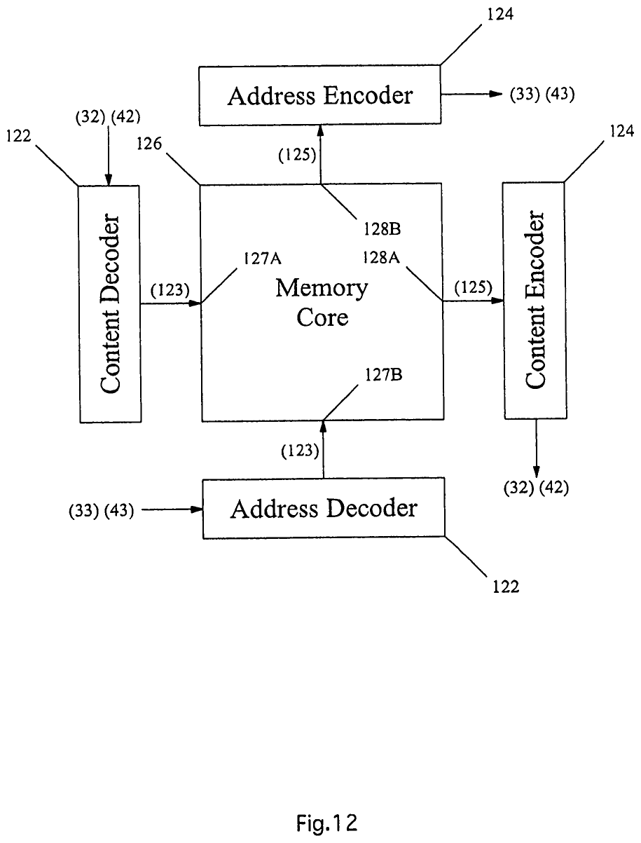

FIG. 12 is a schematic diagram illustrating an embodiment of symbol transformer machine 31 in memory means.

Memory means configured for creating, storing and memorizing associations, couplings and transforms between and among content symbol (32), address symbol (33), content symbol part (42) and address symbol part (43), reduce development, design, test and application efforts. Whereby cost and reliability characteristics of the machine improve.

One of the many embodiments of symbol transformer machine 31 using an ordinary memory machine or device, comprises

x. one or a plurality of decoder means 122 for converting inputted content symbol (32), address symbol (33), content symbol part (42) and address symbol part (43) to decoder output signal (123);
y. one or a plurality of encoder means 124 for converting inputted encoder input signal (125) to content symbol (32), address symbol (33), content symbol part (42), and address symbol part (43);
z. one or a plurality of memory core means 126, coupled by first and second plurality of inputs 127A and 127B to decoder means 122, and by first and second plurality of outputs 128A and 128B to encoder means 124; for receiving at least a pair of decoder output signals (123) from decoder means 122, for creating and storing associations, couplings and transforms between and among a plurality of second decoder output signals (123), and for outputting encoder input signal (125).

The hardware and operation of memory machines, devices and cores are well known to those who are skilled in the art.

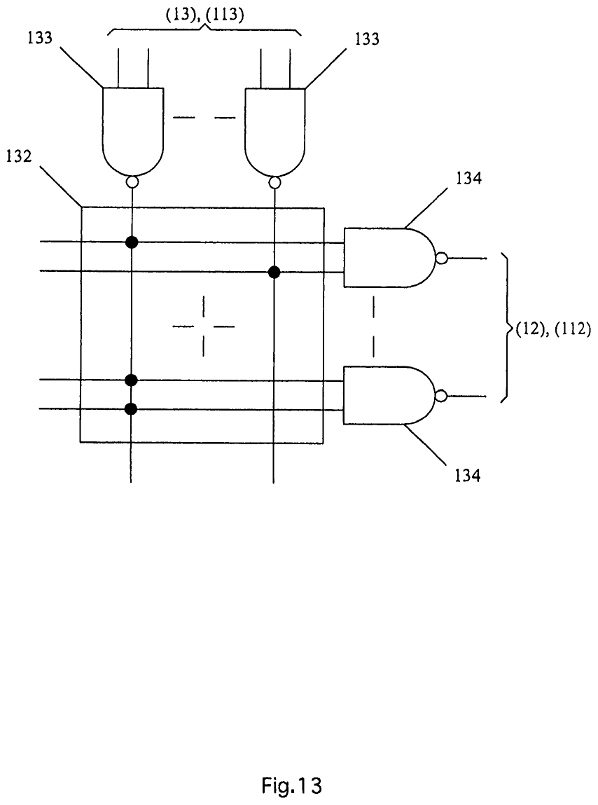

FIG. 13 is a logic diagram illustrating an embodiment of the machine of invention 31 in logic gate means.

The logic gate means are configured for providing associations, couplings and transforms between and among content symbol bit (13), address symbol bit (12), content symbol part bit (112) and address symbol part bit (113), for storing and memorizing these associations, couplings and transforms, and for reducing design, development and test times. Whereby cost and reliability characteristics improve.

One of the many possible embodiments in logic gate means comprises

x. first plurality of logic gate means 133 for providing logic NAND functions;
y. a second plurality of logic gate means 134 for providing logic NAND functions;
z. crosspoint array 132, wherein the memory elements 91 of crosspoint array 132 are coupled with and to a plurality of outputs of first plurality of logic gate means 133 and to a plurality of inputs of second plurality of logic gate means 134, for providing arbitrary programming between and among of the outputs and inputs of first plurality of logic gate means 133 and second plurality of logic gate means 134.

Logic gates, systems and circuits and their operations are well known to those who are skilled in the alt.

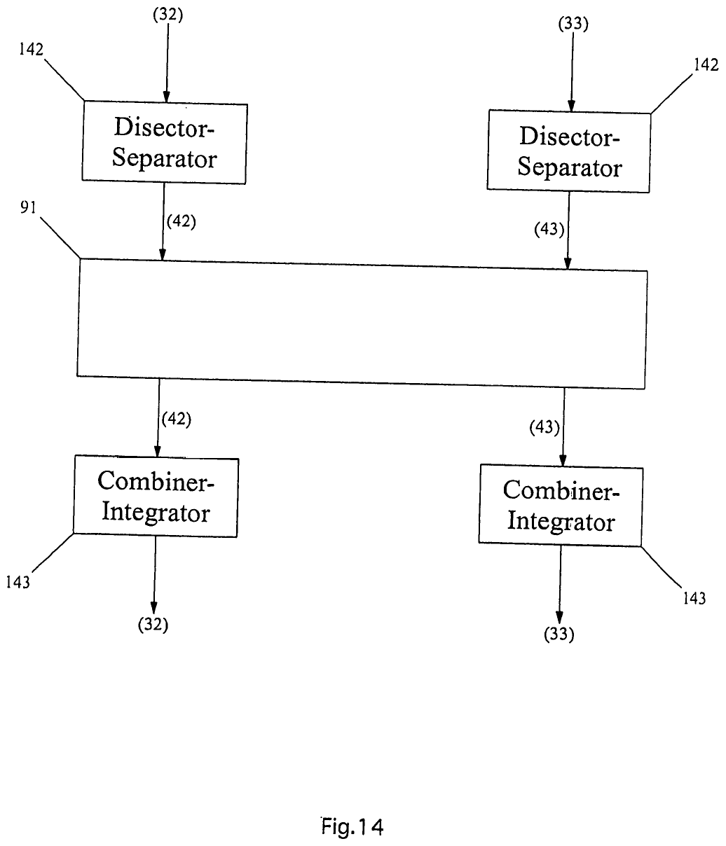

FIG. 14 is a schematic diagram illustrating a first augmented machine of invention 31, configured to operate on and with content symbol parts (42) and address symbol parts (43), greatly reduces the number of memory elements and complexity. Whereby said characteristics greatly improve.

The machine of invention configured to operate on and with content symbol parts (42) and address symbol parts (43) further comprises

f. one or a plurality of dissector-separator means 142, coupled directly or indirectly with and to, or incorporated by symbol transformer means 91, for breaking up content symbol (32) and address symbol (33) and for providing content symbol parts (42), or address symbol parts (43), or both types of symbol part presentments;
g. one or a plurality of combiner-integrator means 143, coupled directly or indirectly with or to, or incorporated by symbol transformer means 91, for uniting content symbol parts (42), or address symbol parts (43), or both types of symbol part presentments and forming content symbol (32) and address symbol (33).

The first augmented machine of invention 31, wherein the plurality of dissector-separator means 142 and the plurality of combiner-integrator means 143 are united in dissector-separator means, further reduces the number of elements and the complexity of the machine 31. Whereby said characteristics improve.

Symbol dissector-separator means 142, combiner-integrator means 143, and combined dissector-separator means are well known to those who are skilled in the art.

The first augmented machine of invention 31, configured to operate on and with polyadic content number (52), polyadic address number (53), polyadic content number part (54) and polyadic address number part (55), further greatly reduces the number of memory and constituent elements and the complexity of the machine. Whereby said characteristics greatly improve.

The first augmented machine of invention 31, configured to operate on and with a plurality of polyadic positional products, or on and with a plurality of polyadic cyphers, further reduces the complexity of the machine 31. Whereby said characteristics further improve.

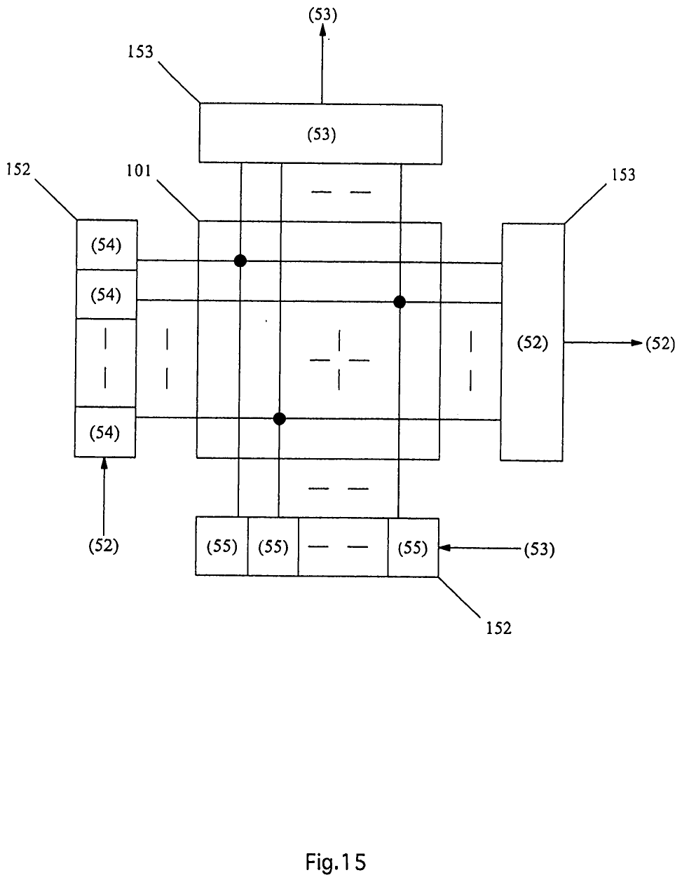

FIG. 15 is a schematic diagram illustrating an embodiment of the first augmented machine of invention 31, wherein the dissector-separator means 142 and combiner-integrator 143 means are symbol registers.

Symbol registers are machines and devices for receiving, storing, breaking into parts, bringing together, distributing and outputting symbols, content symbols (32), address symbols (33), content symbol parts (42) and address symbol parts (43), further reduce the complexity of the machine 31. Whereby said characteristics further improve.

One of the many embodiments of the first augmented machine of invention 31 configured to operate on and with content symbol parts and address symbol parts, comprises

x. one or a plurality of first symbol registers 152, coupled directly or indirectly with or to one or a plurality of crosspoint arrays 101, for dissecting, and separating polyadic content number (52) and polyadic address number (53) into pluralities of polyadic content number parts (54) and polyadic address number parts (55), respectively;
y. one or a plurality of second symbol registers 153, coupled directly or indirectly with or to one or a plurality of crosspoint arrays 101, for combining and integrating the pluralities of content number parts (54) address number parts (55) into polyadic content number (52) and address number (53), respectively;
z. one or a plurality of crosspoint arrays 101, for creating, storing and memorizing associations, couplings and transforms between and among one or a plurality of polyadic content number parts (54) and one or a plurality of address number parts (55).

Registers and their operations are well known machines and devices to those who are skilled in the art.

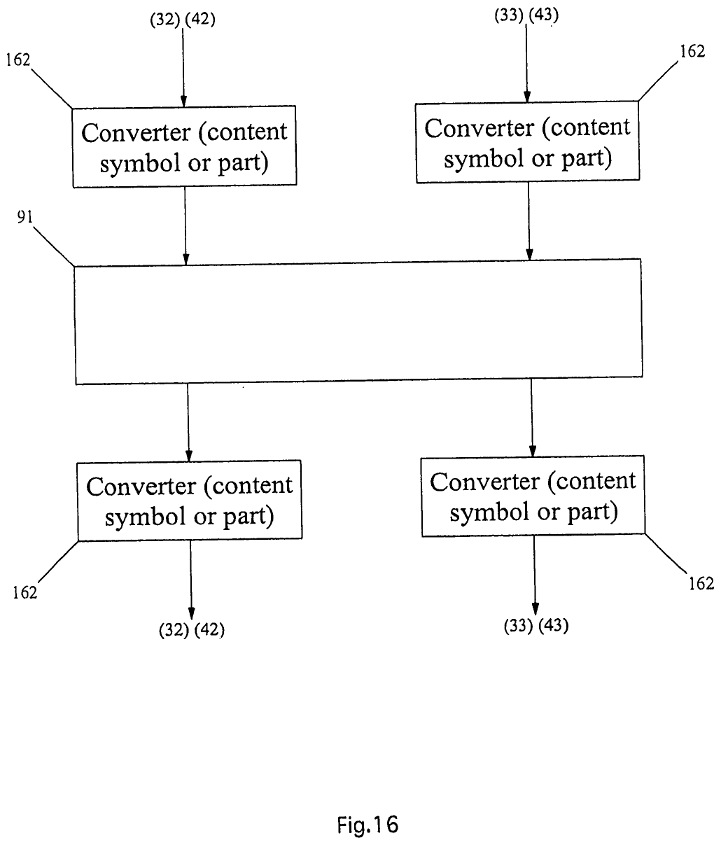

FIG. 16 is a schematic diagram illustrating a second augmented machine of invention 31 configured to operate on and with one or a plurality of symbol converter means 162, for converting a first symbol standing for or suggesting a specific thing or function to a second symbol standing for or suggesting the same specific thing or function as the first symbol does.

The machine of invention 31 augmented with symbol converter 162, reduces the number of memory elements. Whereby said characteristics improve.

The second augmented machine of invention 31 further comprises

h. one or a plurality of symbol converter means 162, coupled directly or indirectly with and to, or incorporated to symbol transformer means 91, for converting content symbol (32), address symbol (33), content symbol part (42) and address symbol part (43) to symbol presentments representing the same information in forms advantageous for the use of symbol transformer means 91 and of one or a plurality of outside receivers, and for reducing the number of memory elements in symbol transformer machines, whereby said characteristics improve.

Symbol converter means and their operations are well known machines and devices to those who are skilled in the art.

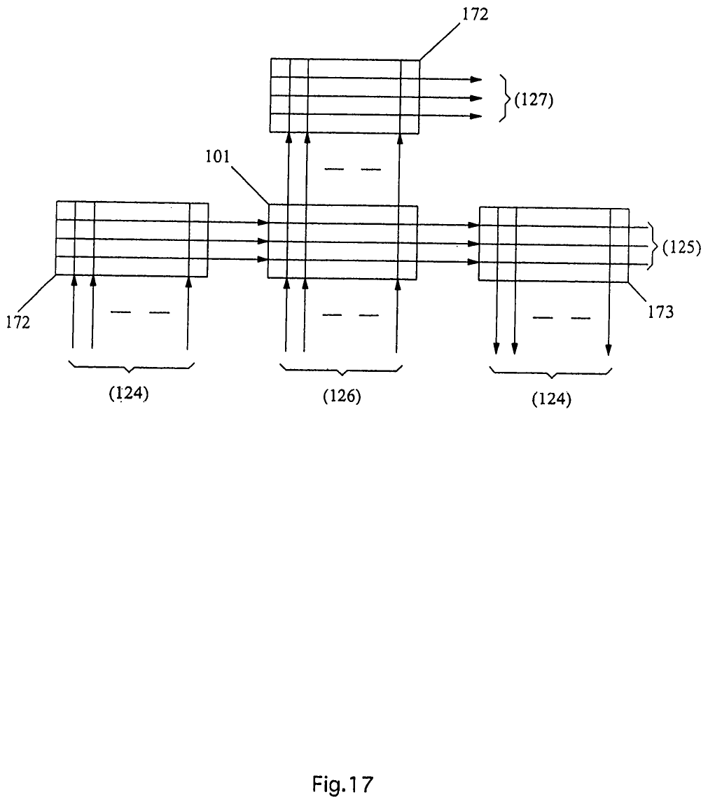

FIG. 17 is a schematic diagram illustrating an embodiment of the second augmented machine of invention 31, wherein the symbol converter means 162 are transcoders, specifically encoders and decoders.

The transcoders, including but not limited to encoders 172, decoders 173, or unified encoder-decoder machines or devices, convert a symbol to a code word, or to a code word to another code word, further reduce the number of memory elements in machine 31. Whereby said characteristics further improve.

One of the many embodiments of the machine of invention 31 configured to operate with transcoder means, comprises

x. one or a plurality of encoders 172, coupled directly or indirectly with and to one or a plurality of crosspoint arrays 101, for converting a first symbol identifier code word (124) representing content symbol (32) and content symbol part (42), to a second symbol identifier code word (125), and for converting another first symbol identifier code word (126) representing address symbol (33) and address symbol part (43), to another second symbol identifier word (127);
y. one or a plurality of decoders 173, coupled directly or indirectly with and to one or a plurality of crosspoint arrays 101, for converting the symbol identifier code word (125) to the first symbol identifier code words (124);
z. one or a plurality of crosspoint arrays 101, for creating, storing and memorizing associations, couplings, and transforms between and among the symbol identifier code word (125) and symbol identifier code word (126).

Transcoder means and their operations are well known to those who are skilled in the art.

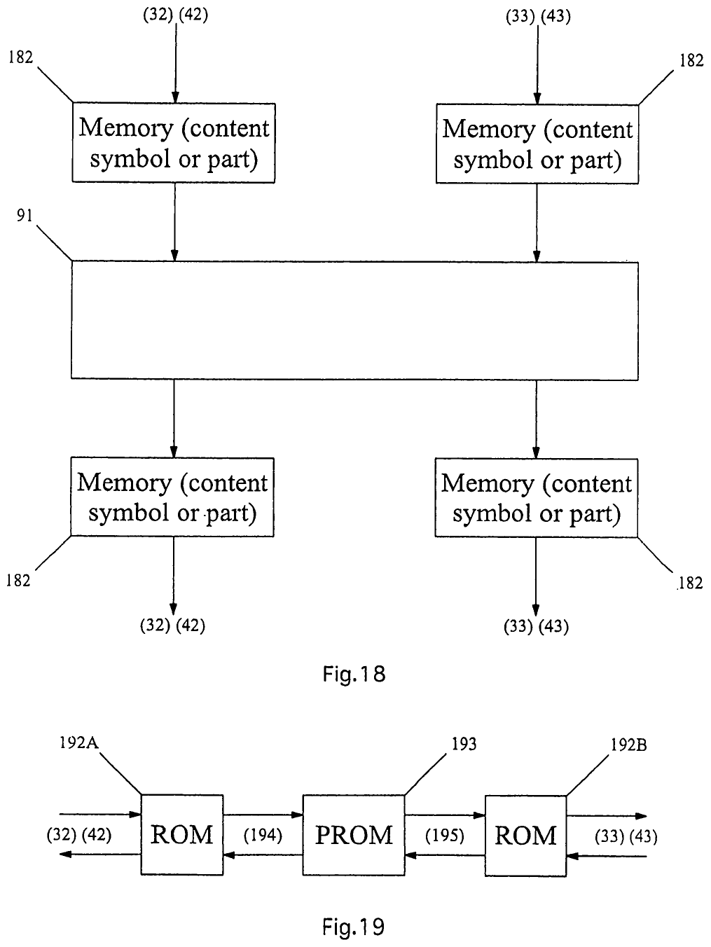

FIG. 18 is a schematic diagram illustrating a third augmented machine of invention 31, configured to shorten the delay path between the source of the symbol and the receptor of the symbol. Whereby said characteristics improve.

The third augmented machine of invention further compromises

i. one or a plurality of auxiliary memory means 182 are coupled directly with and to, or incorporated by symbol transformer means 91, for storing and converting one or a plurality of content symbols (32), address symbols (33), content symbol parts (42) and address symbol parts (43).

Memory means are well known machines and devices to those who are skilled in the art.

FIG. 19 is a schematic diagram illustrating the third augmented machine of invention 31, wherein the auxiliary memory means are memory machines or devices.

Auxiliary memory machines and devices, including but not limited to programmable, write-read, read only, random access, serial access and content addressable memories, reduce the number of memory elements in and the complexity of the symbol transformer machine 31. Whereby said characteristics further improve.

One of the many embodiments of the symbol transformer machine configured to operate with auxiliary memory means, comprises

x. one or a plurality of first read only memories 192A coupled with and to one or a plurality of programmable memories 193, for storing and converting pluralities of content symbols (32) and content symbol parts (42) to one or a plurality of content symbol identifier code words (194), and for performing the storing and converting in the reverse order;
y. one or a plurality of second react only memories 19213, coupled with and to one or a plurality of programmable memories 193. for storing and converting pluralities of address symbol (33) and address symbol parts (43) to one or a plurality of address symbol identifier code words (195), and for performing the storing and converting in the reverse order;
z. one or a plurality of programmable memories 193 for programming, storing, memorizing and accessing one or a plurality of content symbol identifier code words (194) and address identifier code words (195).

The hardware and operation of memory means, including but not limited to read only and programmable memories, are well known to those who are skilled in the art.

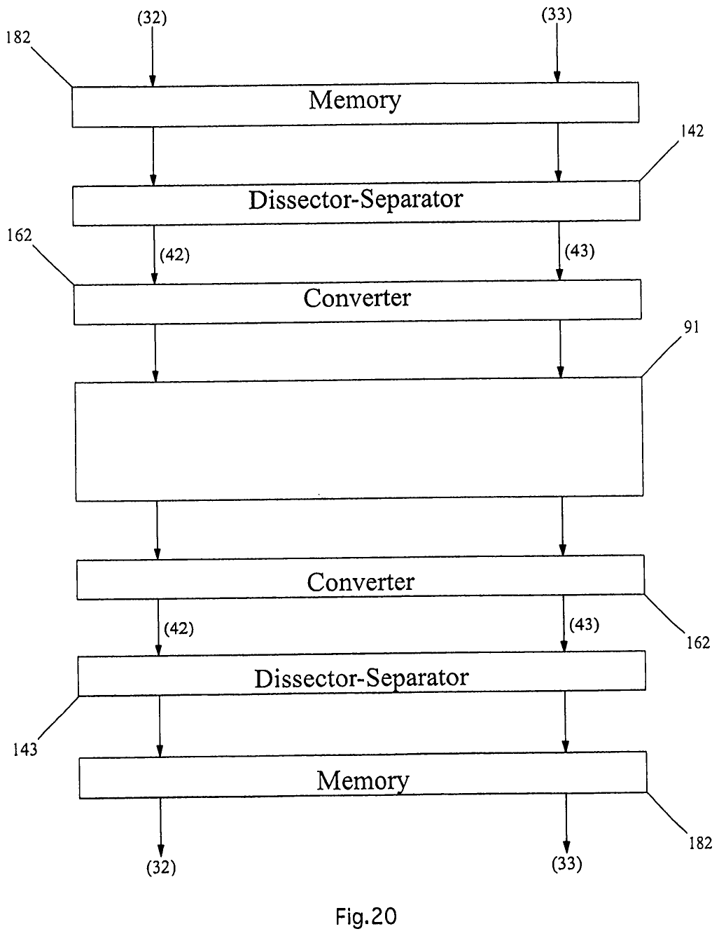

FIG. 20 is a schematic diagram illustrating the symbol transformer machine of invention 31 further comprising one of the many possible combinations of the introduced constituent elements.

The machine of invention 31 compromises the application of any or all of the plurality of the introduced constituent elements, in any combination to and in any apparatus, for specializing, improving and optimizing the apparatus; whereby the variety of uses, manufacturability and said characteristics improve.

One of the many possible combinations comprises a. first auxiliary memory 182, b. dissector-separator 142 coupled to first auxiliary memory 182, c. first converter 162 coupled to dissector-separator 142, d. symbol transformer means 91 coupled to converter 162, e. second converter 162 coupled to symbol transformer means 91, f. combiner-integrator 143 coupled to second converter 162, g. second auxiliary memory 182 coupled to combiner-integrator 143.

The machine of invention is for use in any system, including but not limited to computing, data processing, telecommunication, information storage and memory, and logic systems and, systems on chip, whereby said characteristics of the system improve.

The machine of invention, furthermore, is for performing logic functions, whereby the aforesaid characteristics of the system and the logic system improve.

1. A method of using a symbol transformer machine to perform information storage and memory functions, including but not limited to program or write, store and memorize, normal read or content addressable read or both types of read operations on and with pluralities of symbols, content symbols, address symbols, content symbol parts and address symbol parts; for greatly reducing, in comparison to the prior art, the number of memory elements, the number of constituent elements in and the complexity of information storage and memory machines; whereby the characteristics of operational speed, power consumption, reliability, radiation hardness, size, weight and cost of said information storage and memory machines, and of systems incorporating said information storage and memory machines greatly improve, comprising the steps of
(a) providing said symbols for something standing for or suggesting something else by reason of association, convention, relationship or resemblance;
(b) applying said content symbol, for information standing for or suggesting a thing or a function to store and memorize;
(c) applying said address symbol for information standing for or suggesting an address for the location of said content symbol;
(d) using said symbol transformer machine to perform said information storage and memory functions, including but not limited to said operations, by creating associations, couplings and transforms among and between said symbols, said content symbols, said address symbols, said content symbols parts and said address symbol parts, and by storing and memorizing said associations, couplings and transforms.

2. The method of claim 1, wherein using said symbol transformer machine to perform said program or write operation, further comprising the steps of
(e) receiving said symbol, said content symbol and said address symbol;
(f) associating, coupling and transforming said content symbol with and to said address symbol, or doing so in reverse order.

3. The method of claim 1, wherein using said symbol transformer machine to perform said store and memorize operation, further comprising the step of
(g) storing and memorizing of associations, couplings and transforms formed between and among said content symbols and said address symbols.

4. The method of claim 1, wherein using of said symbol transformer machine to perform said normal read operation further comprising the steps of
(h) receiving said address symbol;
(i) providing said content symbol associated, coupled and transformed with and to received said address symbol;
(j) outputting said content symbol.

5. The method of claim 1, wherein using of said symbol transformer machine to additionally or alternatively perform said content addressable or reversed read operations, further comprising the steps of
(k) receiving said content symbol or part of said content symbol,
(l) providing said address symbol and said content symbol associated, coupled and transformed with and to received said content symbol or received part of said content symbol,
(m) outputting said address symbol, or said content symbol, or both said address symbol and said content symbol.

6. The method of claim 1, wherein said symbols, said content symbol, and said address symbol are in one or a plurality of the symbol classes, comprising:
number; numeral; cypher; letter; image; sign; signal; function; mathematical expression; physical expression; wave; frequency; timing; energy; power; electric-electronic quality and quantity; magnetic quality and quantity; light quality and quantity; sound quality and quantity; mechanical quality and quantity; thermal quality and quantity; kinetic quality and quantity; material quality and quantity; nuclear quality and quantity; biological quality and quantity; radiation quality and quantity; for using a variety and combination of symbol representation, whereby the application area of said method and symbol transformer machine expands.

7. The method of claim 1, wherein said symbols, said content symbol and said address symbol are represented by one or a plurality of codes, where a code is a system of symbols, for further reducing the complexity of said machine and said operations, whereby said characteristics greatly improve.

8. The method of claim 1, wherein said symbols, said content symbol and said address are represented by one or a plurality of numbers in one or a plurality of number systems, for further reducing the number of memory and constituent elements and the complexity of said machine and the complexity of said operations, whereby said characteristics greatly improve.

9. The method of claim 8, wherein said number system is the decimal number system, having ten cyphers representing 0, 1, 2, 3, 4, 5, 6, 7, 8 and 9, for conforming with human computing and data processing traditions, for reducing and eliminating encoding, decoding and other symbol conversion processes, and for simplifying said operations, whereby said characteristics further improve.

10. The method of claim 8, wherein said number system is the binary number system, having two cyphers representing 0 and 1, for complying with prior art computing and data processing standards, for reducing and eliminating encoding, decoding and other symbol conversion processes, and for simplifying said operations, whereby said characteristics further improve.

11. The method of claim 1, wherein using of said symbol of transformer machine further includes performing said operations on and with said symbol parts, said content symbol part and said address symbol parts, for further reducing the number of memory and constituent elements and the complexity of said machine, whereby said characteristics greatly improve.

12. The method of claim 1 further comprising the step of
(n) dissecting and separating said content symbol to a plurality of content symbol parts.

13. The method of claim 1 further comprising the step of
(o) dissecting and separating said address symbol to a plurality of address symbol parts.

14. The method of claim 1 further comprising the step of
(p) using said symbol transformer machine or performing said operations with and on a plurality of said content symbol parts and said address symbol parts.

15. The method of claim 1 further comprising the step of
(q) combining and integrating a plurality of said content symbol parts to form said content symbol.

16. The method of claim 1, further comprising the step of
(r) combining and integrating a plurality of said address symbol parts to form said address symbol.

17. The method of claim 1, wherein the size of said content symbol parts and said address symbol parts is the same, for further reducing the number of memory elements and the complexity of said symbol transformer machine, whereby said characteristics further improve.

18. The method of claim 1, wherein the number of said content symbol parts and the number of said address symbol parts is the same, for further reducing the complexity of said symbol transformer machine, whereby said characteristics further improve.

19. The method of claim 1, wherein said content symbol, said address symbol, said content symbol part and said address symbol part are represented by a polyadic content number, a polyadic address number, a polyadic content number part and a polyadic address number part, respectively; satisfying the law of representation for a polyadic number system that defines a polyadic number as the combinative sum of a plurality of positional products, and defines said positional product as a positional cypher multiplied by a polyadic basis on the power of a positional number; for further greatly reducing the number of the memory and constituent elements in and the complexity of said machine, whereby said characteristics further greatly improve.

20. The method of claim 19, wherein said polyadic content number part and said polyadic address number part are said positional component products, for further reducing the complexity of said method and said machine, whereby said characteristics further improve.

21. The method of claim 19, wherein said polyadic content number part and said polyadic address number part are said positional cyphers in a single polyadic number system having a common polyadic basis, for further reducing the number of constituent elements, and the complexity of said method and said machine, whereby said characteristics further improve.

22. The method of claim 1, wherein the using of said symbol transformer machine further includes converting a first symbol, standing for or suggesting a specific thing or function, to a second symbol, standing for or suggesting the same specific thing or function as the first symbol presentments do, for simplifying said operations and reducing the number of memory and constituent elements of said machine, whereby said characteristic further improve.

23. The method of claim 1, further comprising the step of
(s) converting said content symbol, or said content symbol part, or a combination of the content symbol presentments.

24. The method of claim 1, further comprising the step of
(t) converting said address symbol, or said address symbol part, or a combination of the content symbol presentments.

25. The method of claim 22, wherein the steps of said converting are steps of transcoding, including but not limited to encoding-decoding or combined encoding-decoding operations for further reducing the number of memory elements of said machine, whereby said characteristics further improve.

26. The method of claim 1, wherein the using of said symbol transformer machine further includes storing a plurality of said symbols, said symbol parts, or a combination of the symbol presentments, for supplementing and taking part in said operations, providing symbol presentments and timing to said machine advantageous to perform said operations, and for reducing the number of said memory and constituent elements and the complexity of said machine, whereby said characteristics improve.

27. The method of claim 1, further comprising the step of
(u) storing a plurality of said content symbols, said content symbol parts, or a combination of the symbol presentments.

28. The method of claim 1, further comprising the step of
(v) storing a plurality of said address symbol, said address symbol parts, or a combination of the symbol presentments.

29. The method of claim 1, further comprising application of any and all of the plurality of said steps, in any combination to and in any apparatus, for specializing, improving and optimizing said characteristics, whereby the performance, reliability, manufacturing, quality, cost and other parameters improve.

30. The method of claim 29, wherein said apparatus is a system.

31. The method of claim 29, wherein said apparatus is a computing system.

32. The method of claim 29, wherein said apparatus is a data processing system.

33. The method of claim 29, wherein said apparatus is a telecommunication system.

34. The method of claim 29, wherein said apparatus is an information storage and memory system.

35. The method of claim 29, wherein said apparatus is a logic system.

36. The method of claim 29, for providing logic functions, whereby any of said characteristics of said apparatus, said system, and said logic system improves.

37. A symbol transformer machine for performing information storage and memory functions, including but not limited to operations of program or write, store and memorize, normal read, or content addressable read, or both types of reads, by changing a symbol standing for or suggesting a thing or function to another symbol standing for or suggesting another thing or function, to greatly reduce, in comparison to the prior art, the number of memory and constituent elements and the complexity of said information storage and memory machine, whereby characteristics of operational speed, power consumption, reliability, radiation hardness, size, weight and cost of said information storage and memory machines, and of apparatus incorporating such machines, greatly improve, comprising at least one or a plurality of symbol transformer means for performing said information storage and memory functions, including but not limited to said operations, by creating associations, couplings and transforms between and among pluralities content symbols, said address symbols, content symbol parts and address symbol parts, in any combination of the symbol presentations, and by storing and memorizing said associations, couplings and transforms.

38. The machine of claim 37, further comprising
one or a plurality of symbol input means, coupled with, to or incorporated by said symbol transformer means, for receiving said content symbol, said address symbol, said content symbol part and said address symbol part.

39. The machine of claim 37, further comprising
one or a plurality of symbol output means, coupled with, to or incorporated by said symbol transformer means, for outputting said content symbol, said address symbol, said content symbol parts and said address symbol part.

40. The machine of claim 37, wherein said input means and said output means are combined in a united symbol input-output means, for reducing the number of constituent elements and the complexity of said machine, whereby said characteristics improve.

41. The symbol transformer means of claim 37, further comprising
a plurality of memory element means, coupled directly or indirectly with and to said input means and said output means; for storing and memorizing said associations, couplings and transforms between and among of a plurality of said content symbols, said address symbols, said content symbol parts, and said address symbol parts.

42. The symbol transformer means of claim 41, wherein said memory element means are programmable memory cells, machines and devices.

43. The symbol transformer means of claim 41, wherein said memories element means are write-read memory cells, machines and devices.

44. The symbol transformer means of claim 41, wherein said memory element means are fixed read-only memory cells, machines and devices.

45. The symbol transformer means of claim 41, wherein said memory elements means are content addressable memory cells, machines and devices.

46. The symbol transformer means of claim 41, wherein said memory element means are shift register cells, machines and devices.

47. The machine of claim 37, wherein the configuration of said plurality of symbol transformer means are the same or similar, for reducing complexity of said machine, whereby cost and manufacturability of said machine improve.

48. The machine of claim 37, wherein said machine is configured and implemented in one or a plurality of technology classes, including but not limited to digital, analog, electric, electronic, magnetic, semiconductor, optical, mechanic, sound, thermal, micro, nano, femto, transistor, atomic, subatomic, nuclear, radiation hardened, light, quantum, wave, hydraulic, biological, pervasive, macro technologies, whereby application area and flexibility of said machine expand.

49. The machine of claim 37, wherein said machine is configured to perform said operations in and with one or a plurality of codes, for reducing the complexity of said machine, whereby said characteristics improve.

50. The machine of claim 37, wherein said machine is configured to perform said operations in and with one or a plurality of number systems, for reducing number of memory and constituent elements and complexity of said machine, whereby said characteristics greatly improve.

51. The machine of claim 50, wherein said machine is configured to perform said operations in a decimal system, for conforming with human computing and data processing traditions, and for reducing and eliminating encoder, decoder and other symbol converter machines and devices, whereby said characteristics further improve.

52. The machine of claim 50, wherein said machine is configured to perform said operations in a binary system, for complying with data processing standards, for reducing and eliminating encoding, decoding and other symbol conversion machines and devices, whereby said characteristics further improve.

53. The machine of claim 37, wherein said machine is configured to perform said operations on and with a plurality of signals of conveyable and detectable physical quantities and qualities, comprising pluralities of content signals, address signals, content signal parts and address signal parts representing pluralities of said content symbols, said address symbols, said content symbol parts and said address symbol parts, for reducing number of constituent element and the complexity of said machine, whereby said characteristics improve.

54. The machine of claim 53, wherein said signals are digital signals.

55. The machine of claim 53, wherein said signals are analog signals.

56. The machine of claim 37, wherein said machine is embodied in one or a plurality of crosspoint arrays for performing said operations on and with pluralities of said content signals, said address signals, said content signal parts and said address signal parts, for reducing complexity of said machine, whereby said characteristics improve, comprising
a plurality of first conveyor line means, for receiving, conveying and outputting said content signal, or said content signal part, or both types of content signal presentments;
a plurality of second conveyor line means, arranged to form a plurality of crosspoints with the plurality of said first conveyor line areas, for receiving, conveying, and outputting said address signal presentments;
a plurality of said memory element means, coupled to said first conveyor line means and to said second conveyor line means at or about said crosspoints, for providing programmable, writable, storable and memorizable or fixed conveyance or nonconveyance states.

57. The machine of claim 37, wherein said machine is embodied in one or a plurality of transistor circuits for performing said operations on and with pluralities of said content symbols, said address symbols, said content symbol parts and said address symbol parts, whereby said characteristics improve.

58. The machine of claim 37, wherein one or a plurality of said transistor circuits are configured in said crosspoint array, comprising
a multiplicity of n-type transistors coupled parallel to each other by their individual gate terminals, drain terminals, and source terminals, for forming one or a multiplicity of input signal conveyor lines, output conveyor lines and a ground terminal, respectively;
a multiplicity of p-type transistors coupled by their individual drain terminals, gate terminals and source terminals to said output signal conveyor line, a united program and a precharge voltage terminal and a supply voltage terminal, respectively, for forming, in combination with said multiplicity of n-type transistors, one or a multiplicity of NOR gates;
said ground terminal, said united program and precharge voltage terminal and said common supply voltage terminal, for receiving energy necessary to the programming and operation of said transistor circuit.

59. The machine of claim 37, wherein said machine is embodied in one or a plurality of memory means for performing said operations on and with pluralities of said content symbols, said address symbols, said content symbol parts and said address symbol parts, to reduce development, design, test and application efforts, whereby cost and reliability characteristics of said machine improve.

60. The machine of claim 37, wherein said memory means for performing said operations are comprising
one or a plurality of decoder means for converting inputted said content symbol, said address symbol, said content symbol part and said address symbol to a decoder output signal;
one or a plurality of encoder memory means for converting an inputted encoder input signal to said content symbol, said address symbol, said content symbol part and said address symbol part;
one or a plurality of memory core means, coupled by a first and a second plurality of inputs to said decoder means, and by a first and a second plurality of outputs to said encoder means, for receiving at least a pair of said decoder output signals from said decoder means, for creating and storing associations, couplings and transforms between and among a plurality of said decoder output signals, and for outputting encoder said input signal to said encoder means.

61. The machine of claim 37, wherein said machine is embodied in one or a plurality of logic gate means, for performing said operations ori and with pluralities of said content symbols, said address symbols, said content symbol parts and said address symbol parts, and for reducing design development and test times, whereby cost and reliability characteristics improve.

62. The machine of claim 37, wherein said machine is embodied in a plurality of logic NAND gates, comprising
a first plurality of logic gate means for providing logic NAND functions;
a second plurality of logic gate means for providing logic NAND functions;
said crosspoint array, wherein said memory elements of said crosspoint array are coupled with and to a plurality outputs of said first plurality of logic gate means and a plurality of inputs of said second plurality of logic gate means, for providing arbitrary connections between and among of pluralities of said outputs and said inputs at a plurality of the crosspoints.

63. The machine of claim 37, wherein said machine is configured to perform said operations on and with pluralities of said content symbol parts and of said address symbol parts, for greatly reducing the number of the memory and constituent elements and the complexity of said machine, whereby said characteristics greatly improve.

64. The machine of claim 37, further comprising
one or a plurality of dissector-separator means, coupled directly or indirectly with and to, or incorporated by said symbol transformer means, for breaking up said content symbol and said address symbol, and providing said content symbol parts, said address symbol parts, or both types of symbol part presentments.

65. The machine of claim 37, further comprising
one or a plurality of combiner-integrator means, coupled directly or indirectly with and to, or integrated by said symbol transformer means, for uniting said content symbol parts and said address symbol parts, and forming said content symbol and said address symbol.

66. The machine of claim 37, wherein said plurality of said dissector-separate means and said combiner-integrator means are united in dissector-integration means, for further reducing the complexity and cost of said machine whereby said characteristics improve.

67. The machine of claim 37, wherein said machine is configured to perform said operations on and with polyadic content numbers, polyadic address numbers, polyadic content number parts, and polyadic address number parts, for greatly reducing the number of memory and constituent elements and the complexity of said machine, whereby said characteristics greatly improve.

68. The machine of claim 67, wherein said polyadic content number parts and said polyadic address number parts are polyadic positional products, for further reducing the complexity of said machines, whereby said characteristics further improve.

69. The machine of claim 67, wherein said polyadic content number parts and said polyadic address symbol parts are cyphers, for further reducing the complexity of said machine, whereby said characteristics further improve.

70. The machine of claim 37, wherein said dissector-separator means and said combiner-integrator means are symbol registers, for receiving, storing, breaking into parts, bringing together, distributing and outputting said symbols, said content symbols, said address symbols, said content symbol parts and said address symbol parts, for further reducing the complexity of the machine whereby said characteristics further improve.

71. The machine of claim 37, further comprising
one or a plurality of first register machines or devices, coupled directly or indirectly with and to one or a plurality of said crosspoint arrays, for dissecting and separating said polyadic content number and said polyadic address number into pluralities of said polyadic content number parts and said polyadic address number parts, respectively;
one or a plurality of second register machines or devices, coupled directly or indirectly with and to one or a plurality of said crosspoint arrays, for combining and integrating the pluralities of said polyadic content number parts and said polyadic address number parts into said polyadic content number and polyadic address number, respectively,
one or a plurality of said crosspoint arrays, for creating, storing and memorizing associations, couplings, and transforms between and among one or a plurality of said polyadic content number parts and one or a plurality of said polyadic address number parts.

72. The machine of claim 37, further comprising
one or a plurality of symbol converter means, coupled directly or indirectly with and to, or incorporated by said symbol transformer means, for converting a first symbol standing for or suggesting a specific thing or function to a second symbol standing for or suggesting the same specific thing or function as said first symbol does, for converting said content symbol, address symbol, content symbol part and said address symbol part to symbol presentments advantageous to said symbol transformer means, said machine, and one or a plurality of outside receivers, and for reducing the number of said memory elements in said machine, whereby said characteristics improve.

73. The machine of claim 37, wherein said converter means are transcoders, such as encoder, decoder, or unified encoder-decoder machines, for further reducing the number of memory elements in said symbol transformer, whereby said characteristics further improve, comprising
one or a plurality of said encoders, coupled directly or indirectly with and to one or a plurality of said crosspoint arrays, for converting a first symbol identifier code word to a second symbol identifier code word;
one or a plurality of said decoders, coupled directly or indirectly with and to one or a plurality of said crosspoint arrays, for converting said second symbol identifier code word for said first identifier code word;
one or a plurality of said crosspoint arrays, for creating, storing and memorizing the associations, couplings and transforms between and among said first symbol identifier code word and said second symbol identifier code word.

74. The machine of claim 37, further comprising
one or a plurality of auxiliary memory means, coupled with and to, or incorporated by said symbol transformer means, for storing and converting one or a plurality of said content symbols, said address symbols, said content symbol parts and address symbol parts to provide symbol presentments and timings advantageous to said machine, to shorten the delay path between the source of the symbols and said symbol transformer means, and to reduce the number of and memory elements and the complexity of said machine, whereby said characteristics greatly improve.

75. The machine of claim 37, wherein said auxiliary memory means are ordinary memory machines or devices, including but not limited to programmable, write-read, read only, random access, serial access and content addressable memories, for reducing the number of memory elements in and the complexity of said machine, whereby said characteristics further improve.

76. The machine of claim 37, further comprising
one or a plurality of first read only memories, coupled with and to one or a plurality of said programmable memories, for storing and converting a plurality of said content symbols and said content symbol parts to a plurality of content symbol identifier code words and of content symbol identifier code word parts, and for performing the storing and conversion in the reverse order;
one or a plurality of second read only memories, coupled with and to one or a plurality of said programmable memories, for storing and converting a plurality of said address symbols and of said address symbol parts to one or a plurality of address symbol identifier codewords and of address symbol identifier code word parts, and for performing the storing and conversion in the reverse order;
one or a plurality of said programmable memories for programming, storing, and memorizing the associations, couplings and transforms between and among or a plurality of said content symbol identifier code words and of said address symbol identifier code words, and between and among of a plurality of said content symbol identifier code word parts and of said address symbol identifier code word parts.

77. The machine of claim 37, said content symbol identifier code word parts, further comprising any or all of the plurality of claimed constituent elements, in any combination to and in any apparatus, for specializing, improving and optimizing the apparatus, whereby the variety of uses, manufacturability and said characteristics improve.

78. The machine of claim 77, for use in any system, including but not limited to computing, data processing, telecommunication, information storage and memory, logic system, and system on chip, whereby any or all of said characteristics of said system improve.

79. The machine of claim 77, for performing logic functions, whereby said characteristics of said system and said logic system improve.
